(19) United States
(12) Patent Application Publication
(10) Pub. No.: US 2009/0057911 A1
(43) Pub. Date: Mar. 5, 2009

(54) METHOD FOR MANUFACTURING A SEMICONDUCTOR ARRANGEMENT, USE OF A TRENCH STRUCTURE, AND SEMICONDUCTOR ARRANGEMENT

(76) Inventors: Thomas Hoffmann, Filderstadt (DE); Stefan Schwantes, Heilbronn (DE)

Correspondence Address: Muncy, Geissler, Olds & Lowe, PLLC, P.O. BOX 1364, FAIRFAX, VA, 22038-1364, US

(21) Appl. No.: 12/203,124

(22) Filed: Sep. 2, 2008

Related U.S. Application Data
(60) Provisional application No. 60/971,880, filed on Sep. 12, 2007.

(30) Foreign Application Priority Data
Aug. 31, 2007 (DE) DE102007041407.4

(51) Int. Cl. H01L 21/768; H01L 23/522

(52) U.S. Cl. 257/773; 438/675; 257/E21.585; 257/E23.142

(57) ABSTRACT

A method for manufacturing a semiconductor arrangement, use of a trench structure, and a semiconductor arrangement is provided that includes a single-crystal semiconductor layer, a conductive substrate region and a buried insulator layer, which isolates the single-crystal semiconductor layer from the conductive substrate region, whereby the conductive substrate region is contacted. A trench structure is formed to separate the single-crystal semiconductor layer into a first semiconductor region outside the trench structure and a second semiconductor region within the trench structure, an opening is formed in the single-crystal semiconductor layer within the second semiconductor region, the buried insulator layer is removed within the opening, and a conductor, which contacts the conductive substrate region and adjoins the second semiconductor region, is introduced into the opening.

This nonprovisional application claims priority to German Patent Application No. 102007041407.4, which was filed in Germany on Aug. 31, 2007, and to U.S. Provisional Application No. 60/971,880, which was filed on Sep. 12, 2007, and which are both herein incorporated by reference.

### BACKGROUND OF THE INVENTION

1. Field of the Invention

The present invention relates to a method for manufacturing a semiconductor arrangement, to the use of a trench structure, and to a semiconductor arrangement.

2. Description of the Background Art

Wafers with a buried insulator layer are being used increasingly for integrated circuits. Such wafers are also called SOI (Silicon On Insulator). A single-crystal semiconductor layer (for example, silicon) is separated from a substrate by the buried insulator layer. It is frequently desirable in this case that the substrate is conductive and can be connected to a desired potential. To this end, the substrate, therefore the back of the wafer, can be provided with a metal layer and connected by means of bonding to a connection.

Alternatively, it is possible to contact the substrate from the front of the wafer.

### SUMMARY OF THE INVENTION

It is therefore an object of an embodiment of the invention to provide a method and a use or a semiconductor arrangement to simplify the manufacturing process as much as possible.

Accordingly, a method for manufacturing a semiconductor arrangement is provided. The starting point is a wafer with a single-crystal semiconductor layer, a conductive substrate region, and a buried insulator layer. Such wafers are called, for example, SOI (silicon on insulator). However, a semiconductor material other than silicon, for example, germanium or gallium arsenide, can also be used for the semiconductor layer. Any insulating layer, preferably silicon dioxide, is suitable as the insulator layer but, for example, silicon nitride can also be used. The conductive substrate region, for example, has a doped semiconductor material such as single-crystal or polycrystalline silicon. Alternatively or in combination, the substrate region may also have a metal, preferably tungsten, or another metal with a high melting point.

The insulator layer is arranged between the single-crystal semiconductor layer and the conductive substrate region, so that the insulator layer isolates the single-crystal semiconductor layer from the conductive substrate region.

It is therefore an objective, in an embodiment, to contact the conductive substrate region from the front of the wafer.

Several process steps are provided for this purpose. A trench structure is formed to separate the single-crystal semiconductor layer into a first semiconductor region outside the trench structure and a second semiconductor region within the trench structure. A trench structure can have, for example, a deep trench. A deep trench in this case has a greater depth (in the vertical direction) than width (in the lateral direction). In contrast, a shallow trench has a greater width than depth. Advantageously, a trench of the trench structure is produced by forming a deep trench within a shallow trench. The trench structure can furthermore have a dielectric for insulation. Preferably, the trench structure of the first semiconductor region is completely isolated from the second semiconductor region in the lateral direction.

An opening is formed in the single-crystal semiconductor layer within the second semiconductor region. Different individual processes can be used to produce the opening. Preferably, the semiconductor material is removed. For example, the semiconductor material can be etched. The options for etching are wet-chemical etching and/or preferably plasma etching (RIE—reactive ion etching). Alternatively, laser ablation is possible. The opening after its formation extends to the buried insulator layer. Preferably, the etching occurs with use of an etchant, which for the etching process has a higher selectivity for the semiconductor material of the semiconductor layer than for the dielectric of the insulator layer, so that the etching process stops substantially at an interface of the insulator layer.

The buried insulator layer is then removed within the opening. Preferably, the etching occurs with use of an etchant, which for the etching process has a higher selectivity for the dielectric of the insulator layer than for the semiconductor material of the semiconductor layer and the material of the conductive substrate region, so that the etching process stops substantially at the interface of the substrate region. It is also possible that the etching occurs partially into the substrate. If an etchant with a lower selectivity for the material of the substrate is used, the etching process is limited by a time measurement.

Next, a conductor, which contacts the conductive substrate region, is introduced into the opening. In this case, the conductor can have one or more materials. Preferably, conductive material is deposited in the opening to introduce the conductor. Doped polycrystalline semiconductor material is introduced preferably as the material of the conductor. Preferably, polycrystalline semiconductor material is applied in a dual function simultaneously to form components (EEPROM, capacitor, or resistor). Alternatively, tungsten can be sputtered or another metal can be deposited electrolytically. It is also possible to apply a layer, for example, a semiconductor material by an epitaxial process.

After introduction of the conductor, the conductor adjoins the second semiconductor region. It is preferable that the conductor is connected conductively to the second semiconductor region at its interface.

The mentioned process steps in this case need not occur immediately one after the other. Thus, cleaning steps, for example, can be provided between the specific process steps, which follow one after the other.

Another aspect of the invention is the use of a trench structure for isolating a contacting structure in the lateral direction. In the lateral direction here means a direction within the wafer surface. The contacting structure is formed for contacting a conductive substrate region. For this purpose, the contacting structure has one or more conductive materials.

The employed trench structure comprises a single-crystal semiconductor region of a single-crystal semiconductor layer. The enclosing is preferably formed in each lateral direction, so that the single-crystal semiconductor region of the trench structure is surrounded.

The trench structure adjoins a buried insulator layer, which isolates the single-crystal semiconductor layer outside the single-crystal semiconductor region from the conductive substrate region in the vertical direction. In the vertical direction here means a direction perpendicular to the wafer surface.

A conductor of the contacting structure is formed within an opening in the single-crystal semiconductor region. The conductor connects the conductive substrate region to the single-crystal semiconductor region in an electrically conductive manner.

Another aspect of the invention is a semiconductor arrangement. The semiconductor arrangement can have a first semiconductor region and a second semiconductor region of a single-crystal semiconductor layer. Furthermore, the semiconductor arrangement has at least one conductive substrate region. Several conductive substrate regions can also be formed, which are isolated from one another, for example, by a dielectric.

Furthermore, the semiconductor arrangement can have a buried insulator layer (SOI), which isolates the first semiconductor region of the single-crystal semiconductor layer from the conductive substrate region. The insulator layer in this case is formed between the first semiconductor region and the conductive substrate.

Furthermore, the semiconductor arrangement can have a trench structure, which separates the first semiconductor region of the single-crystal semiconductor layer from the second semiconductor region of the single-crystal semiconductor layer.

Furthermore, the semiconductor arrangement can have a contacting structure. The contacting structure has a conductor, which is arranged within an opening, extending to the substrate region, in the second semiconductor region. The conductor adjoins both the substrate region and the second semiconductor region.

According to an another embodiment, the trench structure can be formed as a closed structure. Preferably, the trench structure here has at least one trench with straight and/or curved sections. Advantageously, the trench structure is formed as a closed ring structure, closed stadium structure, or closed rectangular structure. Preferably, at least one trench of the trench structure adjoins the buried insulator layer. It is also preferable that the second semiconductor region is completely isolated in the lateral direction by the closed trench structure. The result is that the second semiconductor region is surrounded by the dielectric. An opening remains, however, in the buried insulator layer for contacting the conductive substrate region.

It is provided in an embodiment that a dielectric can be introduced for insulation, such as, for example, silicon dioxide, in the at least one trench. In addition, other materials can fill the trench. Preferably, the trench structure is filled at least partially with a dielectric particularly for the lateral isolation between the first semiconductor region and the second semiconductor region. For this purpose, for example, silicon dioxide or silicon nitride can be deposited on the walls of the trench structure.

In fact, it is possible that the opening can be adjacent to the trench structure. The opening can also be arranged at a distance from the trench structure by appropriate masking. Preferably, the opening is arranged within the second semiconductor region to form the closed trench structure in the central region. The options for centering depend here on the precision of the production process. The size of the second semiconductor region is preferably determined depending on this precision.

In an embodiment, the opening can be produced together with the trench structure in an etching step or several etching steps. Preferably, a single mask is provided for masking the trench structure and the opening.

According to an embodiment, the opening can be used as masking, if the buried insulator layer is removed within the opening. It must be ensured here that the trench structure is covered by a mask. Preferably, in this case the buried insulator layer within the trench structure is protected from an etch attack by this masking.

It is also provided that the second substrate region can be contacted with a metal contact in such a way that the second substrate region connects the metal contact with the conductor in an electrically conductive manner. For contacting with the metal contact, dopants are introduced in the second substrate region preferably at the interface between the second substrate region and the metal contact. Preferably, the dopant concentration at the interface is so high that an ohmic contact forms.

According to different embodiment variants, the conductor can have a polycrystalline semiconductor material or a metal or a combination of semiconductor material and metal. Preferably, the metal has a high melting point, such as, for example, in the case of tungsten.

It is provided in an embodiment that at least one active component, particularly a transistor, can be formed in the first semiconductor region. Preferably, the active component is formed in such a way that at least one electric property, such as a breakdown voltage, depends on the potential of the conductive substrate region. A component of this type is, for example, a DMOS field-effect transistor, whereby the conductive substrate region functions as a back electrode.

The previously described refinement variants are especially advantageous both individually and in combination. In this regard, all refinement variants can be combined with one another. Several possible combinations are explained in the description of the exemplary embodiment shown in the figures. These possible combinations of the refinement variants depicted there are not definitive, however.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic sectional view through a wafer;

FIGS. 2a to 2g show schematic sectional views through a wafer at different time points in the manufacturing process of a first exemplary embodiment; and

FIGS. 3a to 3g show schematic sectional views through a wafer at different time points in the manufacturing process of a second exemplary embodiment.

### DETAILED DESCRIPTION

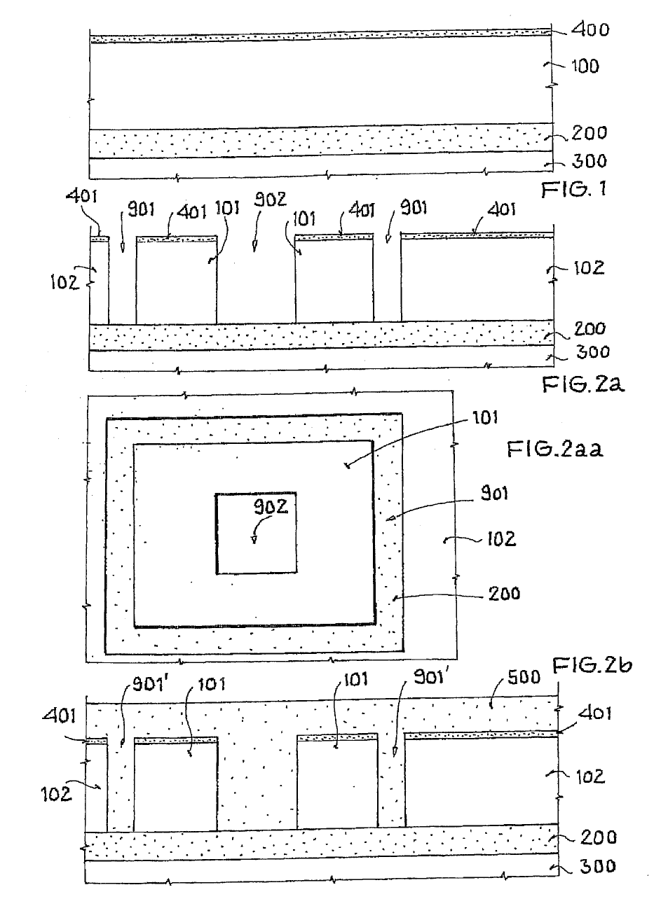

A sectional view through a wafer in the initial state is shown schematically in FIG. 1. A buried insulator layer 200 is arranged on a single substrate region 300. A single-crystal semiconductor layer 100 is arranged above insulator layer 200. An oxide layer 400 is formed above single-crystal semiconductor layer 100. For example, in the two embodiment variants described hereinafter, substrate region 300 includes silicon, buried insulator layer 200 of silicon dioxide, and single-crystal semiconductor layer 100 of silicon. The mentioned materials are in fact advantageous, but can also be replaced by other materials known in semiconductor production.

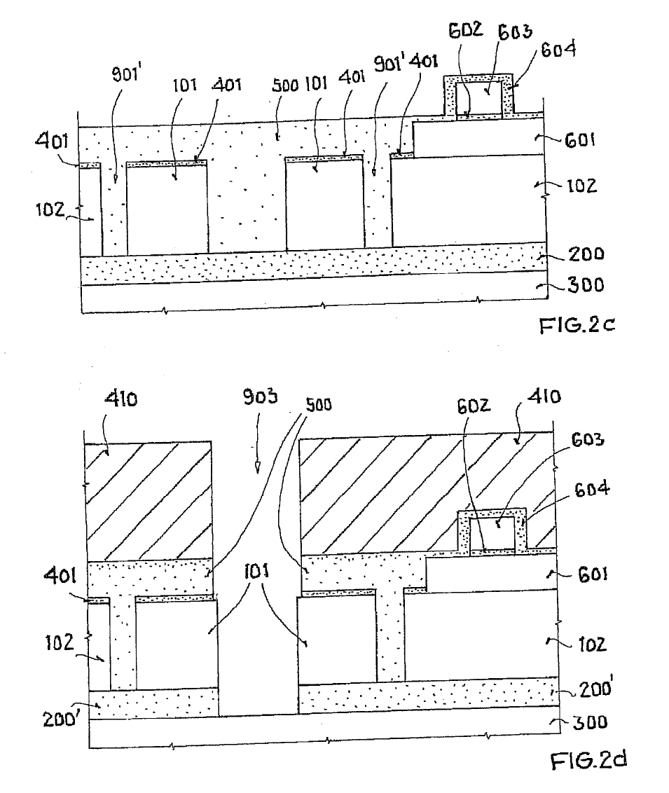

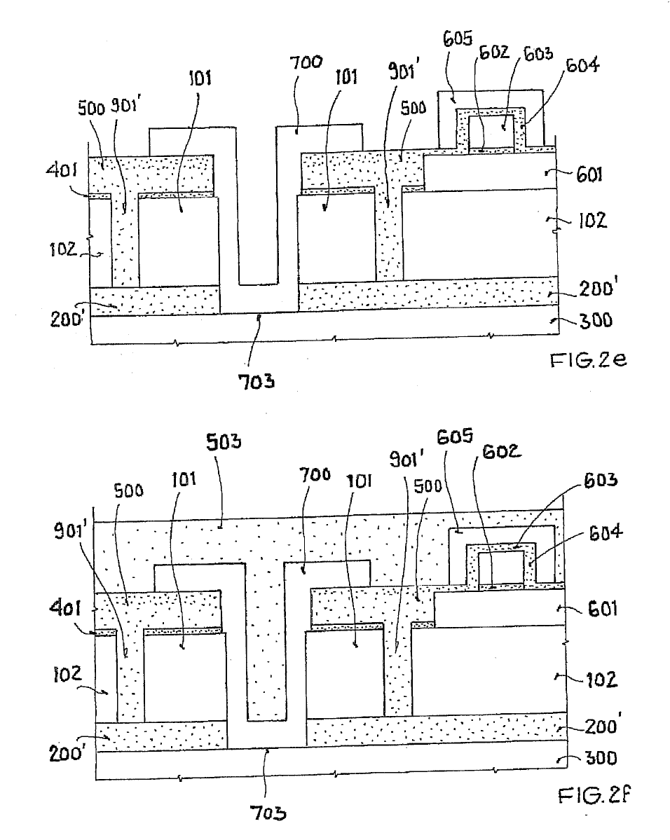

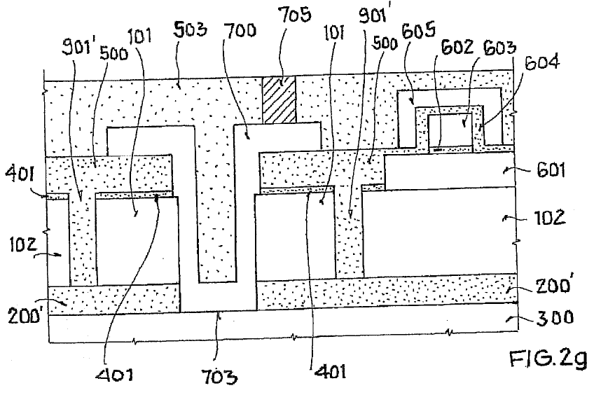

In the first embodiment variant, shown schematically in FIGS. 2a to 2g, oxide layer 400 is patterned first as a 50 nm-thick oxide hard mask 401 (not shown in FIG. 2a). Etching of trenches occurs next by means of oxide hard mask 401 with two different widths. Trench 901 of a trench structure has a width of 800 nm. In contrast, an opening 902 is etched at the same time which has a width of 2000 nm. Opening 902 is used later for contacting of substrate region 300. The rather narrow trench 901 is a standard trench in the manufacturing process and is used later for the lateral isolation of the contact.

Single-crystal semiconductor layer 100 (see FIG. 1) is separated into a first single-crystal semiconductor region 102 and a second single-crystal semiconductor region 101 by standard trench 901. Trench 901 is formed here as a closed structure around opening 902, as is evident from FIG. 2aa. Here, oxide hard mask 401 is not shown in FIG. 2aa.

In FIG. 2b, trench 901 and opening 902 have been filled with a dielectric 500. Dielectric 500, for example, is a 1100 nm-thick TEOS filling. Trench structure 901′ therefore now has a dielectric filling.

In FIG. 2c, the state of the process after the formation of a CMOS component is shown schematically. Single-crystal semiconductor region 601 has been produced previously by epitaxy with a desired dopant concentration. A gate oxide 602 and a gate electrode 603 have been formed from polycrystalline silicon on semiconductor region 601. Gate electrode 603 is covered by an oxide layer 604.

To form an opening 903 extending to substrate region 300, first a mask 410 is formed by application of a photoresist and then photolithographic patterning, as shown in FIG. 2d. Alternatively, the masking can also be achieved by a so-called hard mask (not shown in FIG. 2d). For example, silicon nitride is deposited and patterned by means of a resist mask. The resist mask is again removed and the remaining hard mask of silicon nitride functions as a protective cover layer during the subsequent etching.

Dielectric 500 is then removed by etching in the area of opening 903. The etching in this case stops at substrate region 300 because of the higher selectivity of the etchant for dielectric 500. In this case, opening 903 is also etched through buried insulator layer 200′, which as a result is opened in the area of the desired contacting.

In the manufacturing process employed in the first exemplary embodiment, a second polycrystalline semiconductor layer is formed, which is then patterned. The second polycrystalline semiconductor layer is advantageously used in the same manufacturing process in the dual function for components to form, for example, a resistor, capacitor, or an EEPROM cell. It is shown schematically in FIG. 2e that polycrystalline semiconductor region 605 together with gate electrode 603 and oxide layer 604 forms a capacitor.

The previous opening 903 is filled with the second polysilicon, which doped and patterned forms conductor 700. The polysilicon in this case has a thickness of 400 nm. Conductor 700 adjoins interface 703 on substrate region 300 and is part of the contacting structure for contacting substrate region 300. At the same time, conductor 700 also adjoins second single-crystal semiconductor region 101 and conductively connects second single-crystal semiconductor region 101 to substrate region 300. Conductor 700 is isolated in the lateral direction by filled trench 901′ of the trench structure. This advantageously ensures that the substrate potential of substrate region 300 can be set independent of a potential in first semiconductor region 102 and thereby in semiconductor region 601 of the CMOS transistor.

Because of the spatial separation of conductor 700 and the isolation by filled trench 901′, both can be optimized separately with respect to their function, without needing significantly more space in the wafer surface. Trench 901′ of the trench structure is thereby optimized with respect to defects in the adjoining first single-crystal semiconductor region 102. In contrast, opening 903 for conductor 700 must be optimized in regard to a secure and reliable contacting of substrate region 300. This is achieved in an advantageous manner by separation of functions according to the exemplary embodiment of FIGS. 2a to 2g.

Next, as shown schematically in FIG. 2f, a dielectric 503 is deposited for insulation. Dielectric 503 is, for example, TEOS.

According to FIG. 2g, standard contact etching and filling are then carried out to produce a metal contact 705 to contact the second polysilicon. Instead of conductor 700, metal contact 705 is introduced to form a connection for substrate region 300 and is part of the contacting structure. The metal of metal contact 705 is, for example, tungsten.

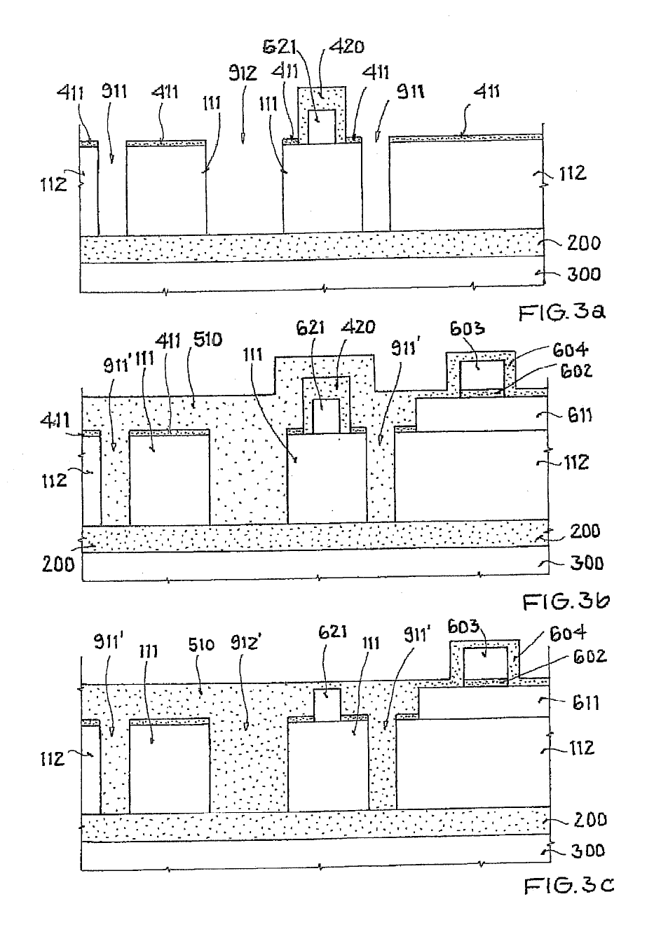

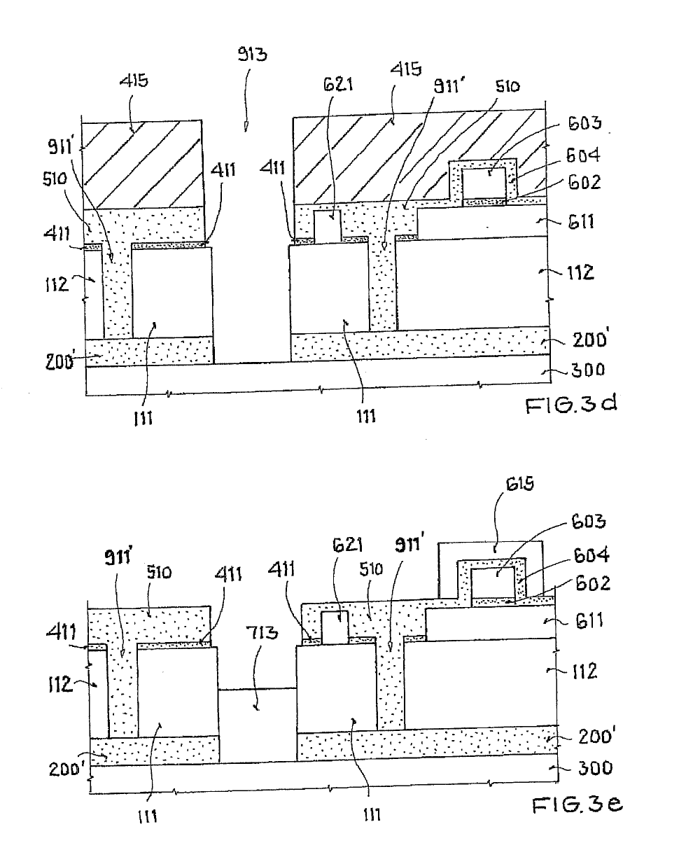

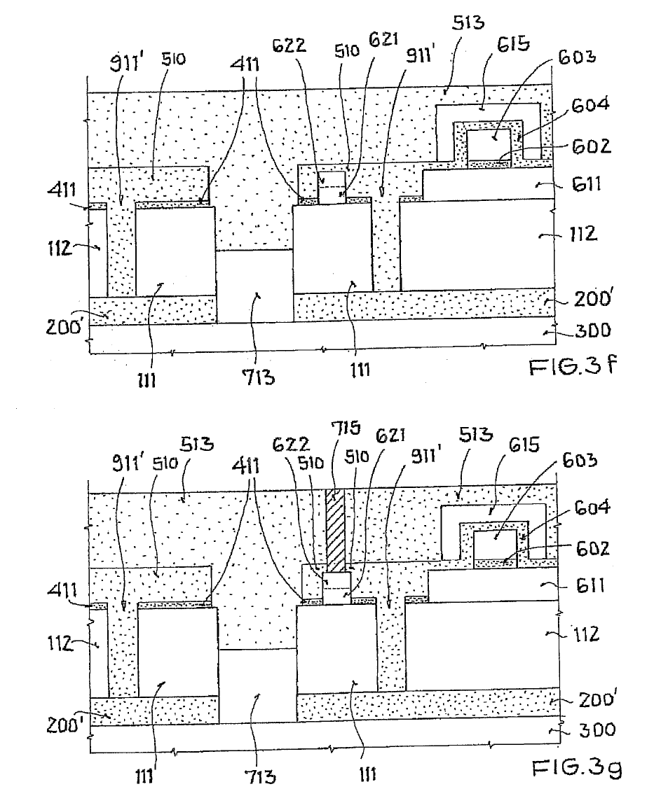

In the second embodiment variant, shown schematically in FIGS. 3a to 3g, oxide layer 400 is patterned first as a 50 nm-thick oxide hard mask 411 (not shown in FIG. 2a). Etching of trenches occurs next by means of oxide hard mask 411 with two different widths. Trench 911 of a trench structure has a width of 800 nm. In contrast, an opening 912 is etched at the same time which has a width of 2000 nm. Opening 912 is used later for contacting of substrate region 300. The narrower trench 911 is a standard trench in the manufacturing process and is used later for the lateral isolation of the contact. Trench 911 is formed by etching a deep trench out of the shallow trench (STI) (not shown in FIG. 3a). Components can be formed adjacent to the shallow trench (STI), whereby a lower defect concentration occurs at the semiconductor surface outside the shallow trench (STI).

Single-crystal semiconductor layer 100 (see FIG. 1) is separated into a first single-crystal semiconductor region 112 and a second single-crystal semiconductor region 111 by standard trench 911. Both single-crystal semiconductor regions, for example, have a dopant concentration above 1e16 cm⁻³. Trench 911 is formed as a closed structure around opening 912.

In FIG. 3b, trench 911 and opening 912 have been filled with a dielectric 510. Dielectric 510, for example, is a 1100 nm-thick TEOS filling. Trench structure 911′ therefore now has a dielectric filling.

In FIG. 3c, the state of the process after the formation of a CMOS component is shown schematically. Single-crystal semiconductor regions 621 and 611 have been formed previously by epitaxy with a desired dopant concentration. A gate oxide 602 and a gate electrode 603 have been formed from polycrystalline silicon on semiconductor region 611. Gate electrode 603 is covered by an oxide layer 604. According to FIGS. 3a and 3b, before the etching of trench 911 and opening 912, a hard mask 420, for example, of silicon nitride is applied to single-crystal semiconductor region 621 to protect single-crystal semiconductor region 621 from the etch attack. The hard mask is removed before the formation of gate oxide 602.

To form an opening 913 extending to substrate region 300, first a mask 415 is produced by application of a photoresist and then photolithographic patterning, as shown in FIG. 3d. Dielectric 510 is then removed by etching in the area of opening 913. The etching in this case stops at substrate region 300 because of the higher selectivity of the etchant for dielectric 510. In this case, opening 913 is also etched through buried insulator layer 200′, which as a result is opened in the area of the desired contacting.

In the manufacturing process employed in the second exemplary embodiment, a second polycrystalline semiconductor layer (400 nm) is formed which is then patterned. The second polycrystalline semiconductor layer is advantageously used in the same manufacturing process in the dual function for components to form, for example, a resistor, capacitor, or an EEPROM cell. It is shown schematically in FIG. 3e that polycrystalline semiconductor region 615 together with gate electrode 603 and oxide layer 604 forms a capacitor.

The previous opening 913 is filled with the second polysilicon, which doped and patterned forms conductor 713. Conductor 713 adjoins interface on substrate region 300 and is part of the contacting structure for contacting substrate region 300. The trench is not covered by a mask during the patterning of the second polysilicon layer. For this reason, a large portion of the polysilicon is again etched out of opening 913. Conductor 713 remains present, however, which adjoins substrate region 300 and second semiconductor region 111 and connects both together in an electrically conductive manner.

Conductor 713 is isolated in the lateral direction by filled trench 911′ of the trench structure. This advantageously ensures that the substrate potential of substrate region 300 can be set independent of a potential in first semiconductor region 112 and thereby in semiconductor region 611 of the CMOS transistor. Because of the spatial separation of conductor 713 and the isolation by filled trench 911′, the surprising effect is achieved that both can be optimized separately with respect to their function, without needing significantly more space in the wafer surface. Trench 911′ of the trench structure is thereby optimized with respect to the defects in the adjoining first single-crystal semiconductor region 112 by formation of shallow trenches (STI). In contrast, opening 913 for conductor 713 must be optimized in regard to a secure and reliable contacting of substrate region 300.

For this purpose, as shown schematically in FIG. 3f, semiconductor region 621 is highly doped at least in region 422. This region directly adjoins region 421, which results in an electrically conductive connection to second semiconductor region 111. The high dopant concentration is advantageously formed synergetically with an implantation for the source or drain regions (not shown in FIG. 3f) of the CMOS transistor.

Furthermore, a dielectric 513 is deposited for insulation. Dielectric 513 is, for example, TEOS.

According to FIG. 3g, standard contact etching and filling are then carried out to manufacture a metal contact 715 to contact highly doped region 422. Highly doped region. 422 thereby enables an ohmic connection to metal contact 715. Instead of highly doped region 422, metal contact 715 is introduced to form a connection for substrate region 300 and is part of the contacting structure. The metal of metal contact 715 is, for example, tungsten.

The exemplary embodiment of FIGS. 3a to 3g has several advantages in comparison with the exemplary embodiment of FIGS. 2a to 2g. Metal contact 715 and the highly doped region 422 enable an especially low-ohmic contact at the conventional level of contacting for the transistors, therefore only requires the use of the already present contacting. Overlapping of edges above the second semiconductor region by the second polysilicon is not necessary and therefore also not process-critical.

A particular advantage of both embodiment variants is that for the standard process with two polysilicon layers only a single additional mask and a single oxide etching step are needed in addition to the standard process, to create a contacting of the substrate region.

The invention is thereby not limited to the shown exemplary embodiments. Instead of the second polysilicon, for example, also a metal, for example, tungsten, can be used as conductor. Other semiconductors, for example, silicon-germanium, can also be used. It is also possible not to form any shallow trench (STI), but to etch solely deep trenches to form the opening for contacting of the substrate region and to form the trench structure.

The functionality of the semiconductor arrangement of FIG. 2g or 3g can be used especially advantageously for a circuit of a smart-power system, particularly with integrated DMOS transistors.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for manufacturing a semiconductor arrangement having a single-crystal semiconductor layer, a conductive substrate region, and a buried insulator layer that isolates the single-crystal semiconductor layer from the conductive substrate region so that the conductive substrate region is contacted, the method comprising:
forming a trench structure to separate the single-crystal semiconductor layer into a first semiconductor region outside the trench structure and a second semiconductor region within the trench structure;
forming an opening in the single-crystal semiconductor layer within the second semiconductor region;
removing the buried insulator layer within the opening; and
introducing a conductor, which contacts the conductive substrate region and adjoins the second semiconductor region, into the opening.

2. The method according to claim 1, wherein the trench structure is formed as a closed structure.

3. The method according to claim 1, wherein the trench structure is filled at least partially with a dielectric for lateral isolation between the first semiconductor region and the second semiconductor region.

4. The method according to claim 1, wherein the trench structure adjoins the buried insulator layer.

5. The method according to claim 1, wherein the opening is arranged at a distance from the trench structure.

6. The method according to claim 1, wherein the opening, together with the trench structure, is formed in an etching step.

7. The method according to claim 1, wherein the opening is used as a mask during the removal of the buried insulator layer within the opening.

8. The method according to claim 7, wherein the trench structure is covered during the removal of the buried insulator layer within the opening.

9. The method according to claim 1, wherein the second semiconductor region is contacted in such a way with a metal contact that the second substrate region connects the metal contact with the conductor in an electrically conductive manner.

10. Use of a trench structure for the lateral isolation of a contacting structure for contacting a conductive substrate region,
wherein the trench structure surrounds a single-crystal semiconductor region of a single-crystal semiconductor layer;
wherein the trench structure adjoins a buried insulator layer, which isolates the single-crystal semiconductor layer outside the single-crystal semiconductor region from the conductive substrate region in a vertical direction; and
wherein a conductor of the contacting structure is formed within an opening in the single-crystal semiconductor region and conductively connects the conductive substrate region with the single-crystal semiconductor region.

11. A semiconductor arrangement comprising:
a first semiconductor region provided in a single-crystal semiconductor layer;
a second semiconductor region provided in the single-crystal semiconductor layer;
a conductive substrate region;
a buried insulator layer, which isolates the first semiconductor region of the single-crystal semiconductor layer from the conductive substrate region;
a trench structure, which separates the first semiconductor region of the single-crystal semiconductor layer from the second semiconductor region of the single-crystal semiconductor layer; and
a contacting structure, which has a conductor, which is arranged within an opening extending to the substrate region in the second semiconductor region and adjoins the substrate region and the second semiconductor region.

12. The semiconductor arrangement according to claim 11, wherein the trench structure adjoins the buried insulator layer.

13. The semiconductor arrangement according to claim 11, wherein the trench structure is a closed structure.

14. The semiconductor arrangement according to claim 11, wherein the conductor has a polycrystalline semiconductor material.

15. The semiconductor arrangement according to claim 11, wherein the conductor has a metal.

16. The semiconductor arrangement according to claim 11, wherein at least one active component is formed in the first semiconductor region.

17. The semiconductor arrangement according to claim 11, wherein the second substrate region is contacted with a metal contact.

18. The semiconductor arrangement according to claim 17, wherein the metal contact is connected ohmically with the conductive substrate region via the second semiconductor region and the conductor.

19. The semiconductor arrangement according to claim 16, wherein the component is a transistor.
